(19) United States
(12) Patent Application Publication
(10) Pub. No.: US 2017/0269640 A1
(43) Pub. Date: Sep. 21, 2017

(54) TWO-WAY ADJUSTABLE STRUCTURE OF HARD DISK BOX

(71) Applicant: INXTRON, INC., New Taipei City (TW)

(72) Inventor: Szu-Tien CHEN, New Taipei City (TW)

(21) Appl. No.: 15/159,977

(22) Filed: May 20, 2016

(30) Foreign Application Priority Data
Mar. 17, 2016 (TW) TW105203707

(51) Int. Cl. G06F 1/18; H05K 7/14

(52) U.S. Cl. CPC G06F 1/181; H05K 7/1488

(57) ABSTRACT

Disclosed is a two-way adjustable structure of hard disk box, comprising a first board, a first side wall, a second side wall and a plurality of fixing bolts. The first board has a first surface and a second surface. The first side wall is vertically mounted at one side of the first board, and is divided into a first portion and a second portion by the first board. The second side wall is vertically mounted at the other side of the first board, and is divided into a first portion and a second portion by the first board. Each pair of some fixing bolts respectively pass through the first side wall and the second side wall at two symmetrical positions. A first accommodating space and a second accommodating space are formed by the first board, the first side wall, and the second side wall.

### BACKGROUND OF THE INVENTION

1. Technical Field

The instant disclosure relates to a structure of hard disk box; in particular, to a two-way adjustable hard disk box for accommodating 2.5-inch hard disks or 3.5-inch hard disks.

2. Description of Related Art

Usually, a traditional hard disk box comprises a top cover, a bottom cover and a circuit board. An accommodating space is formed by the top cover and the bottom cover to have the circuit board configured in, wherein a transmission interface of the circuit board is exposed for electrically connecting with other electric devices. With the Internet and the electric commerce developed, it is common to contain the array storage device, such as a hard disk, in a server for backing up and storing files or video data. These files and video data may be huge, so how to have more storage devices in a server instead of costing more money and spending more space for having more servers has become a topic worth discussing.

### SUMMARY OF THE INVENTION

Considering the topic described above, the instant disclosure provides a two-way adjustable structure of hard disk box to decrease the cost and the space needed by additional hard disks for backing up and storing files or video data which may be a huge amount of data.

The two-way adjustable structure of hard disk box comprises a first board, a first side wall, a second side wall and a plurality of fixing bolts. The first board has a first surface and a second surface. The first side wall is vertically mounted at one side of the first board, and is divided into a first portion and a second portion by the first board. The second side wall is vertically mounted at the other side of the first board, and is divided into a first portion and a second portion by the first board. Each pair of some fixing bolts respectively pass through the first portion of the first side wall and the second portion of the second side wall at two symmetrical positions, and each pair of the other fixing bolts respectively pass through the second portion of the first side wall and the first portion of the second side wall at two symmetrical positions. A first accommodating space is formed by the first surface of the first board, the first portion of the first sidewall and the first portion of the second sidewall, and a second accommodating space is formed by the second surface of the first board, the second portion of the first sidewall and the second portion of the second sidewall.

In one embodiment of the instant disclosure, the fixing bolts are a plurality of first adjusting bolts and second adjusting bolts. The first adjusting bolts respectively pass through the first portion of the first side wall and the second portion of the second side wall. The second adjusting bolts respectively pass through the first portion and the second portion of the first side wall and the first portion and the second portion of the second side wall.

In one embodiment of the instant disclosure, the first accommodating space is for accommodating a 2.5-inch hard disk or a 3.5-inch hard disk, and the second accommodating space is for accommodating a 2.5-inch hard disk or a 3.5-inch hard disk.

In one embodiment of the instant disclosure, the first adjusting bolts are configured to fix the 2.5-inch hard disk and the second adjusting bolts are configured to fix the 3.5-inch hard disk.

In one embodiment of the instant disclosure, the first side wall and the second side wall have the same structure.

In one embodiment of the instant disclosure, the first board is made of metal.

In one embodiment of the instant disclosure, the first side wall and the second side wall are made of metal.

In one embodiment of the instant disclosure, the first side wall is integrally formed with the first board.

In one embodiment of the instant disclosure, the second side wall is integrally formed with the first board.

In one embodiment of the instant disclosure, the two-way adjustable structure of hard disk box further comprises a second board. The second board is mounted between the second portion of the first side wall and the second portion of the second side wall, wherein the second board is perpendicular to the second portion of the first side wall and the second portion of the second side wall and parallel with the second surface of the first board.

To sum up, the two-way adjustable structure of hard disk box comprising the first board, the first side wall, the second side wall, the second board and fixing bolts can provide two accommodating spaces and each of them can accommodate either a 2.5-inch hard disk or a 3.5-inch hard disk. The 2.5-inch hard disk can be fixed by one first adjusting bolt, and the 3.5-inch hard disk can be fixed by second adjusting bolts depending on users' needs. Thereby, the two-way adjustable structure of hard disk box provided by the instant disclosure can decrease the cost and the space needed by additional hard disks for backing up and storing files or video data that may include a huge amount of data.

For further understanding of the instant disclosure, reference is made to the following detailed description illustrating the embodiments and examples of the instant disclosure. The description is only for illustrating the instant disclosure, not for limiting the scope of the claim.

### BRIEF DESCRIPTION OF THE DRAWINGS

Embodiments are illustrated by way of example and not by way of limitation in the FIGURES of the accompanying drawings, in which like references indicate similar elements and in which:

FIG. 1 shows a schematic diagram of a two-way adjustable structure of hard disk box of one embodiment of the instant disclosure.

### DETAILED DESCRIPTION OF PREFERRED EMBODIMENTS

The aforementioned illustrations and following detailed descriptions are exemplary for the purpose of further explaining the scope of the instant disclosure. Other objectives and advantages related to the instant disclosure will be illustrated in the subsequent descriptions and appended drawings. In the drawings, the size and relative sizes of layers and regions may be exaggerated for clarity.

It will be understood that, although the terms first, second, third, and the like, may be used herein to describe various elements, components, regions, layers and/or sections, these elements, components, regions, layers and/or sections should not be limited by these terms. These terms are only to distinguish one element, component, region, layer or section from another region, layer or section discussed below could be termed a second element, component, region, layer or section without departing from the teachings of the instant disclosure. As used herein, the term “and/or” includes any and all combinations of one or more of the associated listed items.

A two-way adjustable structure of hard disk box is provided by the instant disclosure. There are two accommodating spaces formed in this structure, and a 2.5-inch hard disk or a 3.5-inch hard disk can be accommodated in each of them by using adjusting bolts. At least one embodiment is herein provided for illustrating but not for restricting the instant disclosure.

[One Embodiment of the Two-Way Adjustable Structure of Hard Disk Box]

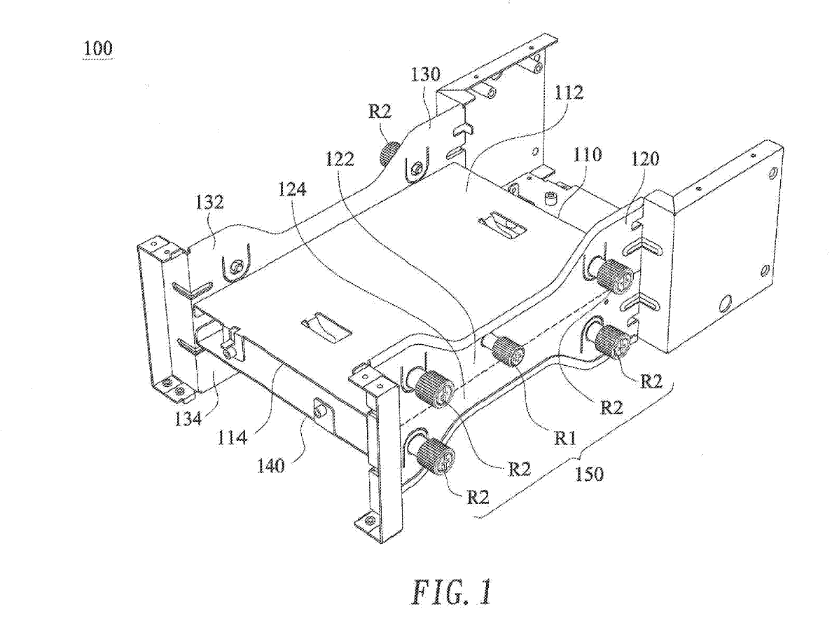

Refer to FIG. 1. FIG. 1 shows a schematic diagram of a two-way adjustable structure of hard disk box of one embodiment of the instant disclosure. The two-way adjustable structure of hard disk box 100 comprises a first board 110, a first side wall 120, a second side wall 130, a second board 140 and a plurality of fixing bolts 150. The first board 110 has a first surface 112 and a second surface 114. The first side wall 120 is vertically mounted at one side of the first board 110. In other words, the first side wall 120 is mounted at one side of the first board 110 and is perpendicular to the first board 110. The first side wall 120 is divided into a first portion 122 and a second portion 124 by the first board 110. The first portion 122 of the first side wall 120 is perpendicularly adjacent to the first surface 112 of the first board 110, and the second portion 124 of the first side wall 120 is perpendicularly adjacent to the second surface 114 of the first board 110. The second side wall 130 is vertically mounted at the other side of the first board 110. In other words, the second side wall 130 is mounted at the other side of the first board 110 and is perpendicular to the first board 110. The second side wall 130 is divided into a first portion 132 and a second portion 134 by the first board 110. The first portion 132 of the second side wall 130 is perpendicularly adjacent to the first surface 112 of the first board 110, and the second portion 134 of the second side wall 130 is perpendicularly adjacent to the second surface 114 of the first board 110. A first accommodating space is formed by the first surface 112 of the first board 110, the first portion 122 of the first sidewall 120 and the first portion 132 of the second sidewall 130, and a second accommodating space is formed by the second surface 112 of the first board 110, the second portion 124 of the first sidewall 120 and the second portion 134 of the second sidewall 130. The second board 140 is mounted between the second portion 124 of the first side wall 120 and the second portion 134 of the second side wall 130, wherein the second board 140 is perpendicular to the second portion 124 of the first side wall 120 and the second portion 134 of the second side wall 130, and is parallel with the second surface 114 of the first board 110.

In this embodiment, the first board 110 and the bottom 140 are made of metal. The first side wall 120 and the second side wall 130 are also made of metal. In addition, the first side wall 120 is integrally formed with the first board 110 and the second board 140, and the second side wall 130 is also integrally formed with the first board 110 and the second board 140.

The following description is for illustrating details of the two-way adjustable structure of hard disk box 100.

In this embodiment, for a part of fixing bolts 150, each pair of fixing bolts 150 respectively pass through the first portion 122 of the first side wall 120 and the second portion 134 of the second side wall 130 at two symmetrical positions. For the other part of fixing bolts 150, each pair of fixing bolts 150 and respectively pass through the second portion 124 of the first side wall 120 and the first portion 132 of the second side wall 130 at two symmetrical positions. It is worth mentioning that, the first side wall 120 and the second side wall 130 has the same structure. Thereby, even though the two-way adjustable structure of hard disk box 100 is turned upside down, the same structure of the two-way adjustable structure of hard disk box 100 can be provided.

The fixing bolts 150 are a plurality of first adjusting bolts R1 and second adjusting bolts R2. As shown in FIG. 1, the first adjusting bolts R1 respectively pass through the first portion 122 of the first side wall 120 and the second portion 134 of the second side wall 130. The second adjusting bolts R2 respectively pass through the first portion 122 and the second portion 124 of the first side wall 120 and the first portion 132 and the second portion 134 of the second side wall 130. In the embodiment, there are five fixing bolts 150 passing through the first side wall 120. Specifically speaking, there are two second adjusting bolts R2 and one first adjusting bolt R1 passing through the first portion 122 of the first side wall 120, and there are two second adjusting bolts R2 passing through the second portion 124 of the first side wall 120. Besides, there are also five fixing bolts 150 passing through the second side wall 130. Specifically speaking, there are two second adjusting bolts R2 passing through the first portion 132 of the second side wall 130, and there are two second adjusting bolts R2 and one first adjusting bolt R1 passing through the second portion 134 of the second side wall 130. It is worth mentioning that, on the first portion 122 of the first side wall 120, the position where the first adjusting bolt R1 passes through is between the two positions where the two second adjusting bolts R2 pass through. Also, on the second portion 134 of the second side wall 130, the position where the first adjusting bolt R1 passes through is between the two positions where the two second adjusting bolts R2 pass through.

The following description is for illustrating details of the fixing bolts 150 of the two-way adjustable structure of hard disk box 100. The first accommodating space of the two-way adjustable structure of hard disk box 100 can be adjusted to accommodate a 2.5-inch hard disk or a 3.5-inch hard disk, and the second accommodating space of the two-way adjustable structure of hard disk box 100 can also be adjusted to accommodate a 2.5-inch hard disk or a 3.5-inch hard disk. The first adjusting bolts R1 are configured to fix the 2.5-inch hard disk and the second adjusting bolts R2 are configured to fix the 3.5-inch hard disk. Specifically speaking, the first adjusting bolt R1 passing through the first portion 122 of the first side wall 120 can fix a 2.5-inch hard disk in the first accommodating space of the two-way adjustable structure of hard disk box 100, and the first adjusting bolt R1 passing through the second portion 134 of the second side wall 130 also can fix a 2.5-inch hard disk in the second accommodating space of the two-way adjustable structure of hard disk box 100. In should be noted that, a 2.5-inch hard disk can be fixed in the first accommodating space or in the second accommodating space only by one first adjusting bolt R1 but no second adjusting bolts R2. On the other hand, the second adjusting bolts R2 passing through the first portion 122 of the first side wall 120 and passing through the first portion 132 of the second side wall 130 can fix a 3.5-inch hard disk in the first accommodating space of the two-way adjustable structure of hard disk box 100, and the second adjusting bolts R2 passing through the second portion 124 of the first side wall 120 and passing through the second portion 134 of the second side wall 130 also can fix a 3.5-inch hard disk in the second accommodating space of the two-way adjustable structure of hard disk box 100. In should be noted that, a 3.5-inch hard disk can be fixed in the first accommodating space or in the second accommodating space only by the second adjusting bolts R2 but no first adjusting bolt R1. Briefly, the two-way adjustable structure of hard disk box 100 provides two accommodating spaces, and each of them can have a 2.5-inch hard disk or a 3.5-inch hard disk fixed therein. Depending on needs, a user can choose to fix a 2.5-inch hard disk by using one first adjusting bolt R1 or choose to fix a 3.5-inch hard disk by using four second adjusting bolts R2.

To sum up, the two-way adjustable structure of hard disk box comprising the first board, the first side wall, the second side wall, the second board and the fixing bolts provides two accommodating spaces, and each of them can accommodate either a 2.5-inch hard disk or a 3.5-inch hard disk. The 2.5-inch hard disk can be fixed by one first adjusting bolt, and the 3.5-inch hard disk can be fixed by four second adjusting bolts depending on users' needs. Thereby, the two-way adjustable structure of hard disk box provided by the instant disclosure can decrease the cost and the space needed by additional hard disks for backing up and storing files or video data that may include a huge amount of data.

The descriptions illustrated supra set forth simply the preferred embodiments of the instant disclosure; however, the characteristics of the instant disclosure are by no means restricted thereto. All changes, alterations, or modifications conveniently considered by those skilled in the art are deemed to be encompassed within the scope of the instant disclosure delineated by the following claims.

1. A two-way adjustable structure of hard disk box, comprising:
a first board, having a first surface and a second surface;
a first side wall, vertically mounted at one side of the first board, divided into a first portion and a second portion by the first board;
a second side wall, vertically mounted at the other side of the first board, divided into a first portion and a second portion by the first board; and
a plurality of fixing bolts, which are a plurality of first adjusting bolts and second adjusting bolts, each pair of some fixing bolts respectively passing through the first portion of the first side wall and the second portion of the second side wall at two symmetrical positions, and each pair of the other fixing bolts respectively passing through the second portion of the first side wall and the first portion of the second side wall at two symmetrical positions;
wherein a first accommodating space is formed by the first surface of the first board, the first portion of the first sidewall and the first portion of the second sidewall, and a second accommodating space is formed by the second surface of the first board, the second portion of the first sidewall and the second portion of the second sidewall;
wherein the first accommodating space is configured for accommodating a 2.5-inch hard disk or a 3.5-inch hard disk and the second accommodating space is configured for accommodating a 2.5-inch hard disk or a 3.5-inch hard disk; and
wherein the first adjusting bolts are configured to fix the 2.5-inch hard disk and the second adjusting bolts are configured to fix the 3.5-inch hard disk.

2. The two-way adjustable structure of hard disk box according to claim 1, wherein the first adjusting bolts respectively pass through the first portion of the first side wall and the second portion of the second side wall, and the second adjusting bolts respectively pass through the first portion and the second portion of the first side wall and the first portion and the second portion of the second side wall.

3-4. (canceled)

5. The two-way adjustable structure of hard disk box according to claim 2, wherein the first side wall and the second side wall have the same structure.

6. The two-way adjustable structure of hard disk box according to claim 1, wherein the first board is made of metal.

7. The two-way adjustable structure of hard disk box according to claim 1, wherein the first side wall and the second side wall are made of metal.

8. The two-way adjustable structure of hard disk box according to claim 1, wherein the first side wall is integrally formed with the first board.

9. The two-way adjustable structure of hard disk box according to claim 1, wherein the second side wall is integrally formed with the first board.

10. The two-way adjustable structure of hard disk box according to claim 1, further comprising a second board, mounted between the second portion of the first side wall and the second portion of the second side wall, wherein the second board is perpendicular to the second portion of the first side wall and the second portion of the second side wall and is parallel with the second surface of the first board.
